(19) United States
(12) Patent Application Publication
(10) Pub. No.: US 2026/0085408 A1
(43) Pub. Date: Mar. 26, 2026

(54) SHIELDING COMPOUND, METHOD OF FORMING THIN FILM USING SHIELDING COMPOUND, AND SEMICONDUCTOR SUBSTRATE AND SEMICONDUCTOR DEVICE FABRICATED USING METHOD

(71) Applicant: SOULBRAIN CO., LTD., Gyeonggi-do (KR)

(72) Inventors: Chang Bong YEON, Gyeonggi-do (KR); Jae Sun JUNG, Gyeonggi-do (KR)

(21) Appl. No.: 19/109,585

(22) PCT Filed: Sep. 7, 2023
(86) PCT No.: PCT/KR2023/013428

§ 371 Date: Mar. 7, 2025

(30) Foreign Application Priority Data
Sep. 7, 2022 (KR) 10-2022-0113344
Sep. 7, 2023 (KR) 10-2023-0118958

(51) Int. Cl. C23C 16/34; C23C 16/455

(52) U.S. Cl. CPC C23C 16/345; C23C 16/45525

(57) ABSTRACT

The present invention relates to a shielding compound, a method of forming a thin film using the shielding compound, and a semiconductor substrate and semiconductor device fabricated using the method. According to the present invention, by providing a compound having a predetermined structure as a shielding compound and forming a shielding area for a silicon-based thin film on a substrate, the deposition rate of a silicon-based thin film may be reduced, and the thin film growth rate may be appropriately reduced. Thus, even when forming a thin film on a substrate with a complex structure, step coverage and the thickness uniformity of the thin film may be greatly improved, corrosion or deterioration may be reduced, the crystallinity of the thin film may be improved, and the electrical properties of the thin film may be improved.

### TECHNICAL FIELD

The present invention relates to a shielding compound, a method of forming a thin film using the shielding compound, and a semiconductor substrate and semiconductor device fabricated using the method. More particularly, according to the present invention, by forming a shielding area for a silicon-based thin film on a substrate to reduce the deposition rate of a silicon-based thin film and appropriately reduce the thin film growth rate, even when forming a thin film on a substrate with a complex structure, step coverage and the thickness uniformity of a thin film may be greatly improved.

### BACKGROUND ART

As the integration of memory and non-memory semiconductor devices continues to increase and the structures thereof become more complex, the importance of step coverage in depositing various thin films on substrates is increasing.

Thin films for semiconductors are made of nitride films, oxide films, metal films, etc. Examples of nitride films include silicon nitride (SiN), titanium nitride (TiN), and tantalum nitride (TaN); examples of oxide films include silicon oxide (SiO₂), hafnium oxide (HfO₂), and zirconium oxide (ZrO₂); and examples of metal films include molybdenum (Mo), tungsten (W), and ruthenium (Ru).

The thin film is generally used as a diffusion barrier between the silicon layer of a doped semiconductor and aluminum (Al), copper (Cu), etc., which are used as interlayer wiring materials. However, when depositing a tungsten (W) thin film on a substrate, the thin film is used as an adhesion layer.

To provide excellent and uniform properties to a thin film deposited on a substrate, it is essential that the formed thin film has high step coverage. Accordingly, the atomic layer deposition (ALD) process, which uses surface reactions, is used rather than the chemical vapor deposition (CVD) process, which mainly uses gaseous reactions. However, there are still problems in implementing 100% step coverage.

In addition, as a way to improve step coverage, methods of reducing the growth rate of thin films have been proposed. However, when deposition temperature is reduced to reduce the growth rate of a thin film, the problem is that the film quality significantly deteriorates due to an increase in the residual amount of impurities, such as carbon or chlorine, within the thin film.

In addition, process by-products such as chloride remain in the manufactured thin film, causing corrosion of metals such as aluminum, and causing deterioration of film quality due to the generation of nonvolatile by-products.

Therefore, it is necessary to develop a method of forming a thin film that allows the formation of a thin film with a complex structure, reduces the residual amount of impurities, and greatly improves step coverage and the thickness uniformity of a thin film, and a semiconductor substrate fabricated using the method.

### RELATED ART DOCUMENTS

### Patent Documents

KR 2011-0048195 A

### DISCLOSURE

### Technical Problem

Therefore, the present invention has been made in view of the above problems, and it is one object of the present invention to provide a shielding compound, a method of forming a thin film using the shielding compound, and a semiconductor substrate fabricated using the method. According to the present invention, by forming a shielding area for a silicon-based thin film on a substrate to reduce the deposition rate of a silicon-based thin film and appropriately reduce the thin film growth rate, even when forming a thin film on a substrate with a complex structure, step coverage and the thickness uniformity of a thin film may be greatly improved.

It is another object of the present invention to improve the density and electrical properties of a thin film by improving the crystallinity of the thin film.

The above and other objects can be accomplished by the present invention described below.

### Technical Solution

In accordance with one aspect of the present invention, provided is a shielding compound for a silicon-based thin film,
wherein the silicon-based thin film has a film composition represented by SixNy (x and y being integers from 0.5 to 4.5, respectively), and
the shielding compound is a saturated compound represented by Chemical Formula 1 below.

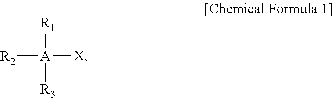

wherein A is carbon;

R₁ and R₃ are independently alkyl groups having 1 to 6 carbon atoms;
R₂ independently has an alkyl group having 1 to 6 carbon atoms or a functional group of a formula of BR₄R₅R₆, wherein B is carbon bonded to A, and R₄, R₅, and R₆ are independently hydrogen, an alkyl group having 1 to 6 carbon atoms, fluorine (F), chlorine (Cl), bromine (Br), or iodine (I); and
X is a halogen element, such as fluorine (F), chlorine (Cl), bromine (Br), or iodine (I).

The shielding compound may have a refractive index (a) of 1.38 to 1.52, and may have a value (b/a) of 0.003 to 0.033, which is obtained by dividing vapor pressure (25° C., mmHg, b) by the refractive index (a).

The silicon-based thin film may be composed of Si₃N₄, Si₂N₃, Si₂N, SiN, or a mixture thereof.

The shielding compound may provide a shielding area for a silicon-based thin film.

The shielding area for a silicon-based thin film may not remain in the silicon-based thin film, and the silicon-based thin film may include a halogen element in an amount of less than 0.01% by weight.

The silicon-based thin film may be used as a diffusion barrier, an etch stop film, or a charge trap.

In accordance with another aspect of the present invention, provided is a method of forming a silicon-based thin film, the method including injecting a shielding compound having a saturated structure represented by Chemical Formula 1 below into a chamber and shielding a surface of a loaded substrate.

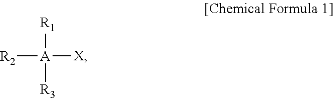

wherein A is carbon;
R₁ and R₃ are independently alkyl groups having 1 to 6 carbon atoms;
R₂ independently has an alkyl group having 1 to 6 carbon atoms or a functional group of a formula of BR₄R₅R₆, wherein B is carbon bonded to A, and R₄, R₅, and R₆ are independently hydrogen, an alkyl group having 1 to 6 carbon atoms, fluorine (F), chlorine (Cl), bromine (Br), or iodine (I); and
X is a halogen element, such as fluorine (F), chlorine (Cl), bromine (Br), or iodine (I).

The method may include vaporizing the shielding compound and forming a shielding area on the surface of the substrate loaded inside the chamber;
performing 1st purging inside the chamber with a purge gas;
vaporizing a precursor compound and adsorbing the precursor compound onto an area outside the shielding area;
performing 2nd purging inside the chamber with a purge gas;
supplying a reaction gas inside the chamber; and
performing 3rd purging inside the chamber with a purge gas.

The method may include vaporizing a precursor compound and adsorbing the precursor compound onto the surface of the substate loaded into the chamber;
performing 1st purging inside the chamber with a purge gas;
vaporizing the shielding compound and shielding the surface of the substate loaded into the chamber;
performing 2nd purging inside the chamber with a purge gas;
supplying a reaction gas inside the chamber; and
performing 3rd purging inside the chamber with a purge gas.

For example, the precursor compound may be a molecule composed of Si and one or more selected from the group consisting of C, N, H, and Cl, preferably a molecule composed of Si and H and Cl. In this case, the deposition rate may be reduced, and the obtained silicon-based thin film may include a halogen element in an amount of less than 0.01%.

The precursor compound may be a silicon precursor having a vapor pressure of 2 mTorr to 75 KTorr at 25° C.

The chamber may be an ALD chamber or a CVD chamber.

The method may include vaporizing the shielding compound or the precursor compound for injection and performing plasma post-treatment.

An amount of purge gas injected into the chamber in the 1st purging step and the 2nd purging step may be 10 to 100,000 times a volume of the injected shielding compound.

The reaction gas may be a nitrifying agent, and the reaction gas, shielding compound, and precursor compound may be transported into the chamber by a VFC, DLI, or LDS method.

The substrate into the chamber may be heated to 300 to 800° C., as a specific example, 500 to 700° C.

A ratio of an amount (mg/cycle) of the shielding compound input into the chamber to an amount (mg/cycle) of the precursor compound input into the chamber may be 1:1.5 to 1:20, as a specific example, 1:3 to 1:15.

In accordance with still another aspect of the present invention, provided is a semiconductor substrate fabricated using the method of forming a silicon-based thin film.

The silicon-based thin film may have a multilayer structure of two or three layers.

The silicon-based thin film may be an Si-rich thin film or a portion of an Si-rich thin film or N-rich thin film.

In accordance with yet another aspect of the present invention, provided is a semiconductor device including the semiconductor substrate described above.

The semiconductor substrate may be low resistive metal gate interconnects, a high aspect ratio 3D metal-insulator-metal (MIM) capacitor, a DRAM trench capacitor, 3D Gate-All-Around (GAA), or a 3D NAND.

### Advantageous Effects

According to the present invention, the present invention has an effect of providing a shielding compound that improves step coverage even when forming a thin film on a substrate with a complex structure by forming a shielded area for silicon-based thin films on the substrate to reduce the deposition rate of a silicon-based thin film and reduce the thin film growth rate appropriately.

In addition, by more effectively reducing process by-products during thin film formation, corrosion or deterioration can be prevented, the crystallinity of a thin film can be improved, and the electrical properties of the thin film can be improved.

In addition, when forming a thin film, process by-products can be reduced, and step coverage and thin film density can be improved. In addition, the present invention has an effect of providing a method of forming a thin film using the shielding compound and a semiconductor substrate fabricated using the method.

### DESCRIPTION OF DRAWINGS

FIG. 1 includes SIMS analysis graphs of SiN thin films manufactured in Example 1 in which the shielding compound according to the present invention is used and Comparative Example 1 in which the shielding compound is not used.

FIG. 2 is a graph showing the change in deposition rate according to the supply time of the shielding compound according to the present invention.

FIG. 3 includes graphs showing the results of depth-dependent elemental analysis through Ar sputtering, for SiN thin films manufactured in Examples 3 and 4 and Comparative Example 4.

FIG. 4 includes SIMS analysis graphs of SiN thin films manufactured in Example 3 and Comparative Example 4.

FIG. 5 includes TEM images confirming the step coverages of SiN thin films deposited using a trench substrate with an aspect ratio of 23:1 in Examples 3 and 4 and Comparative Example 4.

### BEST MODE

Hereinafter, a shielding compound for a silicon-based thin film according to the present invention, a method of forming a silicon-based thin film using the shielding compound and a semiconductor substrate fabricated using the method are described in detail.

In the present disclosure, unless otherwise specified, the term “shielding” means reducing, inhibiting, or blocking adsorption of a precursor compound for forming a silicon-based thin film onto a substrate, and also reducing, inhibiting, or blocking adsorption of process by-products onto the substrate.

In the present disclosure, unless otherwise specified, the terms “a part of a region” or “a part of a substrate” refer to a portion of a particular layer relative to a horizontal plane of a substrate, or to a portion of a particular layer relative to a vertical plane of a substrate.

The present inventors confirmed that, when using a shielding compound to shield a precursor compound for forming a silicon-based thin film on the surface of a substrate loaded inside a chamber, a shielding area that does not remain on the silicon-based thin film was formed at a reduced deposition rate, and the thin film growth rate was significantly reduced. Thus, even when the shielding compound was applied to a substrate with a complex structure, by ensuring the uniformity of the thin film, step coverage was greatly improved. In particular, deposition in a thin thickness was possible. In addition, halides remaining as process by-products and residual carbon that is difficult to reduce even with excessive reducing gas were improved. Based on these results, the present inventors conducted further studies on a shielding compound for providing a shielded area to complete the present invention.

The shielding compound of the present invention provides a shielding compound for a silicon-based thin film.

For example, the silicon-based thin film may be provides using one or more precursors selected from the group consisting of SiH₄, SiCl₄, SiF₄, SiCl₂H₂, Si₂Cl₆, TEOS, DIPAS, BTBAS, (NH₂)Si(NHMe)₃, (NH₂)Si(NHEt)₃, (NH₂)Si(NHⁿPr)₃, (NH₂)Si(NHⁱPr)₃, (NH₂)Si(NHⁿBu)₃, (NH₂)Si(NHⁱBu)₃, (NH₂)Si(NH^{t}Bu)₃, (NMe₂)Si(NHMe)₃, (NMe₂)Si(NHEt)₃, (NMe₂)Si(NHⁿPr)₃, (NMe₂)Si(NHⁱPr)₃, (NMe₂)Si(NHⁿBu)₃, (NMe₂)Si(NHⁱBu)₃, (NMe₂)Si(NH^{t}Bu)₃, (NEt₂)Si(NHMe)₃, (NEt₂)Si(NHEt)₃, (NEt₂)Si(NHⁿPr)₃, (NEt₂)Si(NHⁱPr)₃, (NEt₂)Si(NHⁿBu)₃, (NEt₂)Si(NHⁱBu)₃, (NEt₂)Si(NH^{t}Bu)₃, (NⁿPr₂)Si(NHMe)₃, (NⁿPr₂)Si(NHEt)₃, (NⁿPr₂)Si(NHⁿPr)₃, (NⁿPr₂)Si(NHⁱPr)₃, (NⁿPr₂)Si(NHⁿBu)₃, (NⁿPr₂)Si(NHⁱBu)₃, (NⁿPr₂)Si(NH^{t}Bu)₃, (NⁱPr₂)Si(NHMe)₃, (NⁱPr₂)Si(NHEt)₃, (NⁱPr₂)Si(NHⁿPr)₃, (NⁱPr₂)Si(NHⁱPr)₃, (NⁱPr₂)Si(NHⁿBu)₃, (NⁱPr₂)Si(NHⁱBu)₃, (NⁱPr₂)Si(NH^{t}Bu)₃, (NⁿBu₂)Si(NHMe)₃, (NⁿBu₂)Si(NHEt)₃, (NⁿBu₂)Si(NHⁿPr)₃, (NⁿBu₂)Si(NHⁱPr)₃, (NⁿBu₂)Si(NHⁿBu)₃, (NⁿBu₂)Si(NHⁱBu)₃, (NⁿBu₂)Si(NH^{t}Bu)₃, (NⁱBu₂)Si(NHMe)₃, (NⁱBu₂)Si(NHEt)₃, (NⁱBu₂)Si(NHⁿPr)₃, (NⁱBu₂)Si(NHⁱPr)₃, (NⁱBu₂)Si(NHⁿBu)₃, (NⁱBu₂)Si(NHⁱBu)₃, (NⁱBu₂)Si(NHⁿBu)₃, (N^{t}Bu₂)Si(NHMe)₃, (N^{t}Bu₂)Si(NHEt)₃, (N^{t}Bu₂)Si(NHⁿPr)₃, (N^{t}Bu₂)Si(NHⁱPr)₃, (N^{t}Bu₂)Si(NHⁿBu)₃, (N^{t}Bu₂)Si(NHⁱBu)₃, (N^{t}Bu₂)Si(NH^{t}Bu)₃, (NH₂)₂Si(NHMe)₂, (NH₂)₂Si(NHEt)₂, (NH₂)₂Si(NHⁿPr)₂, (NH₂)₂Si(NHⁱPr)₂, (NH₂)₂Si(NHⁿBu)₂, (NH₂)₂Si(NHⁱBu)₂, (NH₂)₂Si(NH^{t}Bu)₂, (NMe₂)₂Si(NHMe)₂, (NMe₂)₂Si(NHEt)₂, (NMe₂)₂Si(NHⁿPr)₂, (NMe₂)₂Si(NHⁱPr)₂, (NMe₂)₂Si(NHⁿBu)₂, (NMe₂)₂Si(NHⁱBu)₂, (NMe₂)₂Si(NH^{t}Bu)₂, (NEt₂)₂Si(NHMe)₂, (NEt₂)₂Si(NHEt)₂, (NEt₂)₂Si(NHⁿPr)₂, (NEt₂)₂Si(NHⁱPr)₂, (NEt₂)₂Si(NHⁿBu)₂, (NEt₂)₂Si(NHⁱBu)₂, (NEt₂)₂Si(NH^{t}Bu)₂, (NⁿPr₂)₂Si(NHMe)₂, (NⁿPr₂)₂Si(NHEt)₂, (NⁿPr₂)₂Si(NHⁿPr)₂, (NⁿPr₂)₂Si(NHⁱPr)₂, (NⁿPr₂)₂Si(NHⁿBu)₂, (NⁿPr₂)₂Si(NHⁱBu)₂, (NⁿPr₂)₂Si(NH^{t}Bu)₂, (NⁱPr₂)₂Si(NHMe)₂, (NⁱPr₂)₂Si(NHEt)₂, (NⁱPr₂)₂Si(NHⁿPr)₂, (NⁱPr₂)₂Si(NHⁱPr)₂, (NⁱPr₂)₂Si(NHⁿBu)₂, (NⁱPr₂)₂Si(NHⁱBu)₂, (NⁱPr₂)₂Si(NHⁿBu)₂, (NⁿBu₂)₂Si(NHMe)₂, (NⁱBu₂)₂Si(NHEt)₂, (NⁿBu₂)₂Si(NHⁿPr)₂, (NⁿBu₂)₂Si(NHⁱPr)₂, (NⁿBu₂)₂Si(NHⁿBu)₂, (NⁿBu₂)₂Si(NHⁱBu)₂, (NⁿBu₂)₂Si(NH^{t}Bu)₂, (NⁱBu₂)₂Si(NHMe)₂, (NⁱBu₂)₂Si(NHEt)₂, (NⁱBu₂)₂Si(NHⁿPr)₂, (NⁱBu₂)₂Si(NHⁱPr)₂, (NⁱBu₂)₂Si(NHⁿBu)₂, (NⁱBu₂)₂Si(NHⁱBu)₂, (NⁱBu₂)₂Si(NH^{t}Bu)₂, (N^{t}Bu₂)₂Si(NHMe)₂, (N^{t}Bu₂)₂Si(NHEt)₂, (N^{t}Bu₂)₂Si(NHⁿPr)₂, (N^{t}Bu₂)₂Si(NHⁱPr)₂, (N^{t}Bu₂)₂Si(NHⁿBu)₂, (N^{t}Bu₂)₂Si(NHⁱBu)₂, (N^{t}Bu₂)₂Si(NH^{t}Bu)₂, Si(HNCH₂CH₂NH)₂, Si(MeNCH₂CH₂NMe)₂, Si(EtNCH₂CH₂NEt)₂, Si(ⁱPrNCH₂CH₂NWPr)₂, Si(iPrNCH₂CH₂NⁱPr)₂, Si(ⁱBuNCH₂CH₂NBu)₂, Si(ⁱBuNCH₂CH₂NⁱBu)₂, Si(^{t}BuNCH₂CH₂N^{t}Bu)₂, Si(HNCHCHNH)₂, Si(MeNCHCHNMe)₂, Si(EtNCHCHNEt)₂, Si(ⁿPrNCHCHNⁿPr)₂, Si(ⁱPrNCHCHNⁱPr)₂, Si(ⁿBuNCHCHNⁿBu)₂, Si(ⁱBuNCHCHNⁱBu)₂, Si(^{t}BuNCHCHN^{t}Bu)₂, (HNCHCHNH)Si(HNCH₂CH₂NH), (MeNCHCHNMe)Si(MeNCH₂CH₂NMe), (EtNCHCHNEt)Si(EtNCH₂CH₂NEt), (ⁿPrNCHCHNⁿPr)Si(ⁿPrNCH₂CH₂NⁿPr), (ⁱPrNCHCHNⁱPr)Si(ⁱPrNCH₂CH₂NⁱPr), (ⁿBuNCHCHNⁿBu)Si(ⁿBuNCH₂CH₂NⁿBu), (ⁱBuNCHCHNⁱBu)Si(ⁱBuNCH₂CH₂NⁱBu), (^{t}BuNCHCHN^{t}Bu)Si(^{t}BuNCH₂CH₂N^{t}Bu), (NH^{t}Bu)₂Si(HNCH₂CH₂NH), (NH^{t}Bu)₂Si(MeNCH₂CH₂NMe), (NH^{t}Bu)₂Si(EtNCH₂CH₂NEt), (NH^{t}Bu)₂Si(ⁿPrNCH₂CH₂NⁿPr), (NH^{t}Bu)₂Si(ⁱPrNCH₂CH₂NⁱPr), (NH^{t}Bu)₂Si(ⁿBuNCH₂CH₂NⁿBu), (NH^{t}Bu)₂Si(ⁱBuNCH₂CH₂NⁱBu), (NH^{t}Bu)₂Si(^{t}BuNCH₂CH₂N^{t}Bu), (NH^{t}Bu)₂Si(HNCHCHNH), (NH^{t}Bu)₂Si(MeNCHCHNMe), (NH^{t}Bu)₂Si(EtNCHCHNEt), (NH^{t}Bu)₂Si(ⁿPrNCHCHNⁿPr), (NH^{t}Bu)₂Si(ⁱPrNCHCHNⁱPr), (NH^{t}Bu)₂Si(ⁿBuNCHCHNⁿBu), (NH^{t}Bu)₂Si(ⁱBuNCHCHNⁱBu), (NH^{t}Bu)₂Si(^{t}BuNCHCHN^{t}Bu), (ⁱPrNCH₂CH₂NⁱPr)Si(NHMe)₂, (ⁱPrNCH₂CH₂NⁱPr)Si(NHEt)₂, (ⁱPrNCH₂CH₂NⁱPr)Si(NHⁿPr)₂, (ⁱPrNCH₂CH₂NⁱPr)Si(NHⁱPr)₂, (ⁱPrNCH₂CH₂NⁱPr)Si(NHⁿBu)₂, (ⁱPrNCH₂CH₂NⁱPr)Si(NHⁱBu)₂, (ⁱPrNCH₂CH₂NⁱPr)Si(NH^{t}Bu)₂, (ⁱPrNCHCHNⁱPr)Si(NHMe)₂, (ⁱPrNCHCHNⁱPr)Si(NHEt)₂, (ⁱPrNCHCHNⁱPr)Si(NHⁿPr)₂, (ⁱPrNCHCHNⁱPr)Si(NHⁱPr)₂, (ⁱPrNCHCHNⁱPr)Si(NHⁿBu)₂, (ⁱPrNCHCHNⁱPr)Si(NHⁱBu)₂, and (ⁱPrNCHCHNⁱPr)Si(NH^{t}Bu)₂. In this case, the effects intended for the present invention may be sufficiently achieved.

ⁿPr stands for n-propyl, ⁱPr stands for iso-propyl, ⁿBu stands for n-butyl, ⁱBu stands for iso-butyl, and ^{t}Bu stands for tert-butyl.

As a specific example, the silicon-based thin film may have a film composition of SixNy.

Here, x and y may be integers from 0.5 to 4.5 respectively.

x and y may preferably be integers from 2.5 to 4.5 respectively.

The silicon-based thin film may be composed of Si₃N₄, Si₂N₃, Si₂N, SiN, or a mixture thereof, without being limited thereto, and may also include SiH and SiOH.

The silicon-based thin film may be used in semiconductor devices not only as a commonly used diffusion barrier, but also as an etch stop film or charge trap.

The shielding compound may be a saturated compound represented by Chemical Formula 1 below.

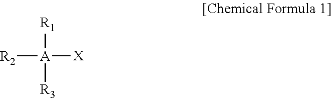

(A is carbon;
R₁ and R₃ are independently alkyl groups having 1 to 6 carbon atoms;
R₂ independently has an alkyl group having 1 to 6 carbon atoms or a functional group of a formula of BR₄R₅R₆, wherein B is carbon bonded to A, and R₄, R₅, and R₆ are independently hydrogen, an alkyl group having 1 to 6 carbon atoms, fluorine (F), chlorine (Cl), bromine (Br), or iodine (I); and
X is a halogen element, such as fluorine (F), chlorine (Cl), bromine (Br), or iodine (I).) In this case, when forming a silicon-based thin film, a shielding area that does not remain in the silicon-based thin film may be formed at a reduced deposition rate, and at the same time, side reactions may be suppressed. In addition, by controlling the thin film growth rate, process by-products within the thin film may be reduced, thereby reducing corrosion and deterioration. In addition, the crystallinity of the thin film may be improved. In addition, even when a thin film is formed on a substrate having a complex structure, step coverage and the thickness uniformity of the thin film may be greatly improved.

In Chemical Formula 1, A is carbon.

R₁, R₂, and R₃ are each independently an alkyl group having 1 to 6 carbon atoms, and at least one thereamong has 2 or 5 carbon atoms. As a preferred example, the carbon number of any one of R₁, R₂, and R₃ is 1, and the carbon number of the other two is 2 or 3. More preferably, the carbon number of any one of R₁, R₂, and R₃ is 1, and the carbon number of the other two is 2. Within this range, the effect of reducing process by-products and the effect of improving thin film density may be increased, and step coverage and the electrical properties of the thin film may be excellent.

In Chemical Formula 1, X may be a halogen element, and may be preferably fluorine, chlorine, or bromine, more preferably chlorine or bromine. Within this range, the effect of reducing process by-products and improving step coverage may be excellent. In addition, X may be, for example, fluorine. In this case, it may be advantageous for processes requiring high temperature deposition.

In Chemical Formula 1, X may be, as another preferred example, iodine. In this case, thin film crystallinity may be improved, side reactions may be suppressed, and the effect of reducing process by-products may be excellent.

The compound represented by Chemical Formula 1 may be a halogen-substituted tertiary alkyl compound. As a specific example, the compound represented by Chemical Formula 1 may may include one or more selected from the group consisting of 2-chloro-2-methylpropane, 2-chloro-2-methylbutane, 2-chloro-2-methylpentane, 3-chloro-3-methylpentane, 3-chloro-3-methylhexane, 3-chloro-3-ethylpentane, 3-chloro-3-ethylhexane, 4-chloro-4-methylheptane, 4-chloro-4-ethylheptane, 4-chloro-4-propylheptane, 2-bromo-2-methylpropane, 2-bromo-2-methylbutane, 2-bromo-2-methylpentane, 3-bromo-3-methylpentane, 3-bromo-3-methylhexane, 3-bromo-3-ethylpentane, 3-bromo-3-ethylhexane, 4-bromo-4-methylheptane, 4-bromo-4-ethylheptane, 4-bromo-4-propylheptane, 2-iodo-2-methylpropane, 2-iodo-2-methylbutane, 2-iodo-2-methylpentane, 3-iodo-3-methylpentane, 3-iodo-3-methylhexane, 3-iodo-3-ethylpentane, 3-iodo-3-ethylhexane, 4-iodo-4-methylheptane, 4-iodo-4-ethylheptane, 4-iodo-4-propylheptane, 2-fluoro-2-methylpropane, 2-fluoro-2-methylbutane, 2-fluoro-2-methylpentane, 3-fluoro-3-methylpentane, 3-fluoro-3-methylhexane, 3-fluoro-3-ethylpentane, 3-fluoro-3-ethylhexane, 4-fluoro-4-methylheptane, 4-fluoro-4-ethylheptane, and 4-fluoro-4-propylheptane, preferably one or more selected from the group consisting of 2-chloro-2-methylpropane, 2-chloro-2-methylbutane, 3-chloro-3-methylpentane, tert-butyl chloride, 2-bromo-2-methylpropane, 2-bromo-2-methylbutane, 3-bromo-3-methylpentane, tert-butyl bromide, 2-iodo-2-methylpropane, 2-iodo-2-methylbutane, 3-iodo-3-methylpentane, tert-butyl iodide, 2-fluoro-2-methyl propane, 2-fluoro-2-methylbutane, 3-fluoro-3-methylpentane, and tert-butyl fluoride. In this case, by providing a shielding area for a silicon thin film, the growth rate of a thin film may be effectively regulated, process by-products may be significantly removed, and step coverage and film quality may be greatly improved.

For example, the compound represented by Chemical Formula 1 may be a saturated compound having a refractive index (a) of 1.38 to 1.52 and a value (b/a) of 0.003 to 0.033 obtained by dividing a vapor pressure (mmHg, b) measured at 25° C. by the refractive index (a). In this case, by forming a shielding area for a silicon-based thin film on a substrate to reduce the deposition rate of a silicon-based thin film and appropriately reduce the thin film growth rate, even when a thin film is formed on a substrate having a complex structure, step coverage and the thickness uniformity of a thin film may be greatly improved. In addition to a thin film precursor, the surface of the substrate may be effectively protected by preventing the adsorption of process by-products, and process by-products may be effectively removed.

As a specific example, the compound represented by Chemical Formula 1 may be a saturated compound having a refractive index (a) of 1.38 to 1.51 and a value (b/a) of 0.003 to 0.0325 obtained by dividing a vapor pressure (mmHg, b) measured at 25° C. by the refractive index (a). Preferably, the compound represented by Chemical Formula 1 may be a saturated compound having a refractive index (a) of 1.383 to 1.505 and a value (b/a) of 0.0035 to 0.0324 obtained by dividing a vapor pressure (mmHg, b) measured at 25° C. by the refractive index (a). In this case, by forming a shielding area for a silicon-based thin film on a substrate to reduce the deposition rate of a silicon-based thin film and appropriately reduce the thin film growth rate, even when forming a thin film on a substrate with a complex structure, step coverage and the thickness uniformity of a thin film may be greatly improved. In addition to a thin film precursor, the surface of the substrate may be effectively protected by preventing the adsorption of process by-products, and process by-products may be effectively removed.

The shielding compound may provide a shielding area for a silicon-based thin film.

For example, the shielding area for a silicon-based thin film may be formed on an entire region or portion of a substrate on which the silicon-based thin film is formed.

The shielding area for a silicon-based thin film does not remain on the silicon-based thin film.

At this time, unless otherwise specified, non-residue refers to a case where the content of C element is less than 0.1 atom %, the content of Si element is less than 0.1 atom %, the content of N element is less than 0.1 atom %, and the content of halogen element is less than 0.1 atom % when analyzed by XPS.

As a specific example, the silicon-based thin film may include a halogen compound in an amount of 0.01% or less.

The silicon-based thin film may be used as a diffusion barrier, an etch stop film, or a charge trap, without being limited thereto.

The shielding compound may be preferably a compound having a purity of 99.9% or more, 99.95% or more, or 99.99% or more. For reference, when a compound having a purity of less than 99% is used, impurities may be formed. Accordingly, it is desirable to use a material having a purity of 99% or more.

The compound represented by Chemical Formula 1 is preferably used in the atomic layer deposition (ALD) process. In this case, the surface of a substrate may be effectively protected and process by-products may be effectively removed without interfering with the adsorption of a precursor compound.

The compound represented by Chemical Formula 1 may be preferably liquid at room temperature (25° C.), and may have a density of 0.8 to 2.5 g/cm³ or 0.8 to 1.5 g/cm³, a vapor pressure (20° C.) of 0.1 to 300 mmHg or 1 to 300 mmHg, and a water solubility (25° C.) of 200 mg/L or less. Within this range, a shielded area may be effectively formed, and step coverage and the thickness uniformity and film quality of a thin film may be greatly improved.

More preferably, the compound represented by Chemical Formula 1 may have a density of 0.75 to 2.0 g/cm³ or 0.8 to 1.3 g/cm³, a vapor pressure (20° C.) of 1 to 260 mmHg, and a water solubility (25° C.) of 160 mg/L or less. Within this range, a shielded area may be effectively formed, and step coverage and the thickness uniformity and film quality of a thin film may be greatly improved.

The method of forming a silicon-based thin film according to the present invention may include a step of injecting a shielding compound represented by Chemical Formula 1 below into an ALD chamber and adsorbing the shielding compound onto the surface of a loaded substrate.

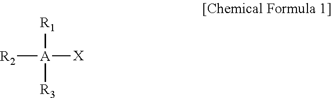

(A is carbon;
R₁ and R₃ are independently alkyl groups having 1 to 6 carbon atoms;
R₂ independently has an alkyl group having 1 to 6 carbon atoms or a functional group of a formula of BR₄R₅R₆, wherein B is carbon bonded to A, and R₄, R₅, and R₆ are independently hydrogen, an alkyl group having 1 to 6 carbon atoms, fluorine (F), chlorine (Cl), bromine (Br), or iodine (I); and
X is a halogen element, such as fluorine (F), chlorine (Cl), bromine (Br), or iodine (I)). In this case, by forming a shielding area for a silicon-based thin film on a substrate to reduce the deposition rate of a silicon-based thin film and appropriately reduce the thin film growth rate, even when forming a thin film on a substrate with a complex structure, step coverage and the thickness uniformity of a thin film may be greatly improved.

In the step of shielding using the shielding compound on the surface of the substrate, the feeding time of the shielding compound on the surface of the substrate may be preferably 0.01 to 20 seconds, more preferably 0.02 to 20 seconds, still more preferably 0.04 to 20 seconds, still more preferably 0.05 to 20 seconds per cycle. Within this range, the thin film growth rate may be reduced, and step coverage and economics may be excellent.

In the present disclosure, the feeding time of the shielding compound is preferably based on a flow rate of 0.5 to 5 mg/s at a chamber volume of 15 to 20 L, more specifically based on a flow rate of 1 to 2 mg/s at a chamber volume of 18 L.

As a preferred example, the method of forming a thin film may include a step of vaporizing the shielding compound to shield the surface of a substrate loaded into an ALD chamber; a step of performing 1st purging inside the chamber with a purge gas; a step of vaporizing a precursor compound and adsorbing the precursor compound onto the surface of the substrate loaded into the chamber; a step of performing 2nd purging inside the chamber with a purge gas; a step of supplying a reaction gas inside the chamber; and a step of performing 3rd purging inside the chamber with a purge gas. At this time, the shielding step to the 3rd purging step may be repeated as a unit cycle until a thin film of the desired thickness is obtained. In this way, in one cycle, when the shielding compound of the present invention is injected before the precursor compound and is absorbed into the substrate, even when deposition is performed at high temperatures, the thin film growth rate may be appropriately reduced, process by-products may be effectively removed, the resistivity of the thin film may be reduced, and the step coverage may be significantly improved.

As another preferred example, the method of forming a thin film may include a step of vaporizing a precursor compound and adsorbing the precursor compound onto the surface of a substrate loaded into a chamber; a step of performing 1st purging inside the chamber with a purge gas; a step of vaporizing the shielding compound and adsorbing the shielding compound onto the surface of the substrate loaded in the chamber; a step of performing 2nd purging inside the chamber with a purge gas; a step of supplying a reaction gas inside the chamber; and a step of performing 3rd purging inside the chamber with a purge gas. At this time, the shielding step to the 3rd purging step may be repeated as a unit cycle until a thin film of the desired thickness is obtained. In this way, in one cycle, when the shielding compound of the present invention is injected after the precursor compound and is absorbed into the substrate, the shielding compound may act as an activator for thin film formation. In this case, the thin film growth rate may be increased, and the density and crystallinity of the thin film may be increased, thereby reducing the resistivity of the thin film and improving the electrical properties of the thin film.

As a preferred example, in the method of forming a thin film according to the present invention, in one cycle, the shielding compound of the present invention may be introduced before the precursor compound and absorbed onto the substrate. In this case, even when depositing a thin film at high temperatures, process by-products may be significantly reduced and step coverage may be significantly improved by appropriately reducing the thin film growth rate. In addition, the crystallinity of the thin film may be increased, thereby reducing the resistivity of the thin film. In addition, even when applied to semiconductor devices with a large aspect ratio, the thickness uniformity of the thin film may be greatly improved, thereby ensuring the reliability of the semiconductor device.

For example, in the method of forming a thin film, when the shielding compound is deposited before or after the deposition of the precursor compound, depending on the needs, the unit cycle may be repeated 1 to 99,999 times, preferably 10 to 10,000 times, more preferably 50 to 5,000 times, still more preferably 100 to 2,000 times. Within this range, the desired thickness of the thin film may be obtained, and the effects intended for the present invention may be sufficiently achieved.

The precursor compound may be a molecule composed of Si and one or more selected from the group consisting of C, N, H, and Cl. When the precursor compound is a silicon precursor having a vapor pressure of 2 mTorr to 75 KTorr at 25° C., despite natural oxidation, the effect of forming a shielding area by the aforementioned shielding compound may be maximized.

For example, in the present invention, the chamber may be an ALD chamber or a CVD chamber.

In the present invention, the shielding compound or the precursor compound may be vaporized, injected, and then subjected to plasma post-treatment. In this case, the growth rate of a thin film may be adjusted, and process by-products may be reduced.

When the shielding compound is first adsorbed on the substrate and then the precursor compound is adsorbed, or when the precursor compound is first adsorbed on the substrate and then the shielding compound is adsorbed, the amount of purge gas injected into the chamber in the step of purging the unadsorbed shielding compound is not particularly limited as long as the amount of purge gas is sufficient to remove the unadsorbed shielding compound. For example, the amount of purge gas may be 10 to 100,000 times, preferably 50 to 50,000 times, more preferably 100 to 10,000 times. Within this range, by effectively removing the unadsorbed shielding compound, a thin film may be formed evenly and deterioration of film quality may be prevented. Here, the input amounts of the purge gas and shielding compound are each based on one cycle, and the volume of the shielding compound refers to the volume of the vaporized shielding compound.

As a specific example, the shielding compound is injected (per cycle) at a flow rate of 1.66 mL/s for an injection time of 0.5 seconds. In the step of purging the unadsorbed shielding compound, when purge gas is injected (per cycle) at a flow rate 166.6 mL/s for an injection time of 3 seconds, the injection amount of purge gas is 602 times the injection amount of shielding compound.

In addition, in the step of purging the unadsorbed precursor compound, the amount of purge gas injected into the ALD chamber is not particularly limited as long as the amount is sufficient to remove the unadsorbed precursor compound. For example, the amount may be 10 to 10,000 times, preferably 50 to 50,000 times, more preferably 100 to 10,000 times the volume of the precursor compound injected into the ALD chamber. Within this range, by sufficiently removing the unadsorbed precursor compound, a thin film may be formed evenly and deterioration of film quality may be prevented. Here, the input amounts of the purge gas and precursor compound are each based on one cycle, and the volume of the precursor compound refers to the volume of the vaporized precursor compound.

In addition, in the purging step performed immediately after the reaction gas supply step, the amount of purge gas injected into the ALD chamber may be 10 to 10,000 times, preferably 50 to 50,000 times, more preferably 100 to 10,000 times the volume of reaction gas injected into the ALD chamber. Within this range, the desired effects may be sufficiently achieved. Here, the input amounts of purge gas and reaction gas are based on one cycle.

The shielding compound and the precursor compound may be transferred into the ALD chamber preferably by a VFC, DLI, or LDS method, more preferably by an LDS method.

For example, the substrate loaded into the chamber may be heated to 300 to 800° C., as a specific example, 500 to 700° C. The shielding compound or the precursor compound may be injected onto the substrate in an unheated or heated state, or may be injected unheated and then heated during the deposition process, depending on the deposition efficiency. For example, the shielding compound or the precursor compound may be injected onto the substrate at 300 to 800° C. for 1 to 30 seconds.

The ratio of amounts (mg/cycle) of the shielding compound and the precursor compound fed into the chamber may be preferably 1:1.5 to 1:20, more preferably 1:2 to 1:15, still more preferably 1:2 to 1:12, still more preferably 1:2.5 to 1:10. Within this range, step coverage may be improved, and process by-products may be greatly reduced.

In the present invention, for example, the precursor compound may be mixed with a non-polar solvent and introduced into the chamber. In this case, the viscosity or vapor pressure of the precursor compound may be easily controlled.

The non-polar solvent may preferably include one or more selected from the group consisting of alkanes and cycloalkanes. In this case, an organic solvent with very low reactivity and easy moisture management may be included. In addition, step coverage may be improved even when deposition temperature increases during thin film formation.

As a more desirable example, the non-polar solvent may include a C1 to C10 alkane or a C3 to C10 cycloalkane, preferably a C3 to C10 cycloalkane. In this case, reactivity may be significantly reduced, and moisture management may be easy.

In the present disclosure, C1, C3, and the like indicate the number of carbon atoms.

The cycloalkane may preferably include C3 to C10 monocycloalkanes, and among the monocycloalkanes, cyclopentane is liquid at room temperature and has the highest vapor pressure, so cyclopentane is preferable in the vapor deposition process, but the present invention is not limited thereto.

For example, the non-polar solvent may have a solubility (25° C.) of 200 mg/L or less, preferably 50 to 400 mg/L, more preferably 135 to 175 mg/L in water. Within this range, the reactivity toward the precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the precursor compound and the non-polar solvent, the non-polar solvent may be included in an amount of 5 to 95% by weight, more preferably 10 to 90% by weight, still more preferably 40 to 90% by weight, most preferably 70 to 90% by weight.

When the content of the non-polar solvent exceeds the above range, impurities may be generated, which may increase the resistance and impurities within a thin film. When the content of the organic solvent is less than the range, the effect of improving step coverage due to solvent addition and the effect of reducing impurities such as chloride (Cl) ions may be reduced.

For example, in the method of forming a silicon-based thin film, when using the shielding compound, the reduction rate of thin film growth rate per cycle (A/cycle) as calculated by Equation 1 below may be −5% or less, preferably −10% or less, more preferably −20% or less, still more preferably −30% or less, still more preferably −40% or less, most preferably −45% or less. Within this range, step coverage and film thickness uniformity may be excellent.

Reduction rate of thin film growth rate per cycle (%)=[(Thin film growth rate per cycle when a shielding compound is used−Thin film growth rate per cycle when a shielding compound is not used)/Thin film growth rate per cycle when a shielding compound is not used]×100 [Equation 1]

In Equation 1, when the shielding compound is used and when the shielding compound is not used, for each case, the thin film growth rate per cycle means the thin film deposition thickness (Å/cycle) per cycle, i.e., the deposition rate. For example, the deposition rate may be obtained as an average deposition rate calculated by measuring the final thickness of a thin film using an ellipsometer, and then dividing the final thickness by the total number of cycles. For more accurate thickness measurement, the optical thickness (ellipsometry) measurement method was correlated with transmission electron microscopy (TEM) analysis to improve the thickness error.

In Equation 1, “when the shielding compound is not used” means that a thin film is manufactured by adsorbing only a precursor compound on a substrate in a thin film deposition process. As a specific example, in the thin film forming method, the above case refers to a case where a thin film is formed by omitting a step of adsorbing a shielding compound and a step of purging an unadsorbed shielding compound.

In the method of forming a silicon-based thin film, the residual halogen intensity (c/s) in the thin film may be preferably 4,000 ppm or less, more preferably 3,700 ppm or less, still more preferably 3,500 ppm or less, still more preferably 2,000 ppm or less, still more preferably 0 ppm or close to 0 ppm as measured using a thin film having a thickness of 100 Å according to SIMS. Within this range, corrosion and deterioration may be effectively prevented.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

The atomic layer deposition (ALD) process is very advantageous in manufacturing integrated circuits (ICs) that require a high aspect ratio. In particular, the ALD process has advantages such as excellent conformality, uniformity, and precise thickness control due to the self-limiting thin film growth mechanism.

For example, the method of forming a thin film may be performed at a deposition temperature of 50 to 800° C., preferably 300 to 700° C., more preferably 500 to 700° C., still more preferably 600 to 650° C. Within this range, a thin film with excellent film quality may be grown while implementing ALD process characteristics.

For example, the method of forming a thin film may be performed at a deposition pressure of 0.01 to 20 Torr, preferably 0.1 to 20 Torr, more preferably 0.1 to 10 Torr, most preferably 0.3 to 5 Torr. Within this range, a thin film having a uniform thickness may be obtained.

In the present disclosure, the deposition temperature and the deposition pressure may be measured as temperature and pressure formed within the deposition chamber, or as temperature and pressure applied to the substrate within the deposition chamber.

The method of forming a silicon-based thin film may preferably include a step of increasing the temperature inside the chamber to the deposition temperature before introducing the shielding compound into the chamber; and/or a step of purging by injecting an inert gas into the chamber before introducing the shielding compound into the chamber.

In addition, as a thin film manufacturing device capable of implementing the silicon-based thin film manufacturing method, the present invention may include a thin film manufacturing device including an ALD chamber, a first vaporizer for vaporizing a shielding compound, a first transport means for transporting the vaporized shielding compound into the ALD chamber, a second vaporizer for vaporizing a thin film precursor, and a second transport means for transporting the vaporized thin film precursor into the ALD chamber. Here, vaporizers and transport means commonly used in the technical field to which the present invention pertains may be used in the present invention without particular limitation.

As a specific example, the method of forming a thin film is explained. First, a substrate on which a thin film is to be formed is placed in a deposition chamber capable of atomic layer deposition.

The substrate may include a semiconductor substrate, such as a silicon substrate or a silicon oxide substrate.

The substrate may further have a conductive layer or an insulating layer formed on the upper portion thereof.

To deposit a thin film on the substrate positioned in the deposition chamber, the above-described shielding compound, a precursor compound, or a mixture of the precursor compound and a non-polar solvent is prepared.

Then, the prepared shielding compound is injected into a vaporizer, is transformed into a vapor phase, is transferred into a deposition chamber, and is adsorbed on a substrate. Then, purging is performed to remove the unadsorbed shielding compound.

Next, the prepared precursor compound or a mixture of the precursor compound and a non-polar solvent (composition for forming a thin film) is injected into the vaporizer, is transformed into a vapor phase, is transferred into the deposition chamber, and is adsorbed on the substrate. Then, the unadsorbed precursor compound/composition for forming a thin film is purged.

In the present disclosure, when necessary, the process of removing the unadsorbed shielding compound by purging after adsorbing the shielding compound on the substrate; and the process of adsorbing the precursor compound onto the substrate and purging to remove the unadsorbed precursor compound may be performed in reverse order.

In the present disclosure, for example, the shielding compound and the precursor compound (composition for forming a thin film) may be delivered into the deposition chamber by vapor flow control (VFC) using mass flow control (MFC) or a liquid delivery system (LDS) using liquid mass flow control (LMFC), preferably an LDS method.

At this time, a mixed gas of one or more selected from the group consisting of argon (Ar), nitrogen (Nd), and helium (He) may be used as a carrier gas or dilution gas to move the shielding compound and the precursor compound onto the substrate, without being limited thereto.

In the present disclosure, for example, an inert gas, preferably the carrier gas or dilution gas may be used as the purge gas.

Next, a reaction gas is supplied. A reaction gas commonly used in the technical field to which the present invention pertains may be used in the present invention without particular limitation. Preferably, the reaction gas may contain a nitriding agent. The nitriding agent and the precursor compound adsorbed on the substrate react to form a nitride film.

Preferably, the nitriding agent may be nitrogen gas (N₂), hydrazine gas (N₂H₄), or a mixture of nitrogen gas and hydrogen gas.

The reaction gas may contain hydrogen (H₂) alone. The hydrogen reacts with the precursor compound adsorbed on the substrate to form a silicon film.

Next, unreacted residual reaction gas is purged using an inert gas. Accordingly, in addition to excess reaction gas, generated byproducts may also be removed.

As described above, in the method of forming a silicon-based thin film, for example, a step of shielding using a shielding compound on a substrate, a step of purging the unadsorbed shielding compound, a step of adsorbing a precursor compound/composition for forming a thin film on the substrate, a step of purging the unadsorbed precursor compound/composition for forming a thin film, a step of supplying a reaction gas, and a step of purging the residual reaction gas may be set as a unit cycle. To form a thin film of desired thickness, the unit cycle may be repeated.

As another example, in the method of forming a silicon-based thin film, a step of adsorbing a precursor compound/composition for forming a thin film on the substrate, a step of purging the unadsorbed precursor compound/composition for forming a thin film, a step of adsorbing a shielding compound on the substrate, a step of purging the unadsorbed shielding compound, a step of supplying a reaction gas, and a step of purging the residual reaction gas may be set as a unit cycle. To form a thin film of desired thickness, the unit cycle may be repeated.

For example, the unit cycle may be repeated 1 to 99,999 times, preferably 10 to 1,000 times, more preferably 50 to 5,000 times, still more preferably 100 to 2,000 times. Within this range, the desired thin film properties may be well expressed.

In addition, the present invention provides a semiconductor substrate, and the semiconductor substrate is fabricated by the silicon-based thin film formation method. In this case, the step coverage and thickness uniformity of a thin film may be excellent, and density and electrical properties may be excellent.

Preferably, the manufactured thin film may have a thickness of 100 nm or less, an etching rate (WER@LAL500 60s) of less than 2 nm/min based on a thin film thickness of 10 or 20 nm, a residual carbon content of 0.01% or less, a residual halogen content of 0.01% or less, and a step coverage of 90% or more. Within this range, the thin film may be used as an insulating film and a charge trap layer, without being limited thereto.

For example, the thin film may have a thickness of 1 to 100 nm, preferably 1 to 50 nm, more preferably 3 to 25 nm, still more preferably 5 to 20 nm. Within this range, thin film properties may be excellent.

The residual carbon content and residual halogen content of the thin film may be preferably 0.1% or less or 0 to 0.01%, still more preferably 0 to 0.001%, still more preferably 0 to 0.0001%, respectively. Within this range, the thin film properties may be excellent, and the thin film growth rate may be reduced. Within this range, due to the appropriate content of carbon in the thin film, a deep trap site is formed within the band gap of the thin film, so that insulating film properties such as charge storage characteristics, film density, and etching rate may be excellent. As the halogen residual amount in the thin film decreases, film quality increases.

For example, the thin film may have a step coverage of 90% or more, preferably 92% or more, more preferably 95% or more. Within this range, since even a thin film of complex structure may be easily deposited on a substrate, the thin film may be applied to next-generation semiconductor devices.

For example, the manufactured thin film may include a silicon nitride film (SiₓN_{y}, here, 0<x≤4.5, 0<y≤4.5, preferably 0.5≤x≤4.5, 0.5≤y≤4.5, more preferably 2.5≤x≤4.5, 2.5≤y≤4.5). In this case, the thin film may be used as a diffusion barrier, etch stop film, or charge trap of a semiconductor device.

For example, when necessary, the thin film may have a multilayer structure of two or three layers. As a specific example, the multilayer film with a two-layer structure may have a lower layer-middle layer structure, and the multilayer film with a three-layer structure may have a lower layer-middle layer-upper layer structure.

For example, the lower layer may be formed of one or more selected from the group consisting of Si, SiO₂, MgO, Al₂O₃, CaO, ZrSiO₄, ZrO₂, HfSiO₄, Y₂O₃, HfO₂, LaLuO₂, Si₃N₄, SrO, La₂O₃, Ta₂O₅, BaO, and TiO₂.

For example, the middle layer may be formed of TiₓN_{y}, preferably TN.

For example, the upper layer may be formed of one or more selected from the group consisting of W and Mo.

Hereinafter, preferred examples and drawings are presented to help understand the present invention, but the following examples and drawings are only illustrative of the present invention, and it is obvious to those skilled in the art that various changes and modifications are possible within the scope and technical idea of the present invention. Such changes and modifications fall within the scope of the appended patent claims.

### EXAMPLES

### Example 1

Tert-butyl iodide as a shielding compound and Si₂Cl₆ as a thin film precursor compound were prepared, respectively.

The prepared shielding compound was placed in a canister and supplied to a vaporizer heated to 120° C. at a flow rate of 0.05 g/min using a liquid mass flow controller (LMFC) at room temperature. The shielding compound vaporized from the vaporizer was injected into a deposition chamber loaded with a substrate for 1 second, and then argon gas was supplied at 5000 sccm for 2 seconds to perform argon purging. At this time, the pressure inside the reaction chamber was controlled to 2.5 Torr.

Next, the prepared Si₂Cl₆ was placed in a separate canister and supplied to a separate vaporizer heated to 150° C. at a flow rate of 0.05 g/min using a liquid mass flow controller (LMFC) at room temperature. After Si₂Cl₆ vaporized from the vaporizer was injected into the deposition chamber for 1 second, argon gas was supplied at 5000 sccm for 2 seconds to perform argon purging. At this time, the pressure inside the reaction chamber was controlled to 2.5 Torr.

Next, ammonia as a reactive gas was injected into the reaction chamber at 1000 sccm for 3 seconds, followed by argon purging for 3 seconds. At this time, the substrate on which a metal thin film is to be formed was heated to 460° C. By repeating this process 200 to 400 times, an SiN thin film (SixNy thin film) (x and y being integers from 0.5 to 4.5 respectively) with a thickness of 10 nm, which is a self-limiting atomic layer, was formed.

To measure the etching rate, an SiN thin film was etched by immersing the SiN thin film in an LAL500 etchant for 60 seconds, and the reduced thickness was measured as an optical thickness to calculate the etching rate.

### Example 2

An SiN thin film, which is a self-limiting atomic layer, was formed in the same manner as in Example 1, except that tert-butyl bromide was used as a shielding compound.

To measure the etching rate, an SiN thin film was etched by immersing the SiN thin film in an LAL500 etchant for 60 seconds, and the reduced thickness was measured as an optical thickness to calculate the etching rate.

### Example 3

Tert-butyl iodide as a shielding compound and Si₂Cl₆ as a thin film precursor compound were prepared, respectively.

The prepared shielding compound was placed in a canister and supplied to a vaporizer heated to 120° C. at a flow rate of 0.1 g/min using a liquid mass flow controller (LMFC) at room temperature. The shielding compound vaporized from the vaporizer was injected into a deposition chamber loaded with a substrate for 5 to 30 seconds, and then argon gas was supplied at 1000 sccm for 30 seconds to perform argon purging. At this time, the pressure inside the reaction chamber was controlled to 1.0 Torr.

Next, the prepared Si₂Cl₆ was placed in a separate canister and supplied to a separate vaporizer heated to 150° C. at a flow rate of 0.1 g/min using a liquid mass flow controller (LMFC) at room temperature. After the thin film precursor compound vaporized from the vaporizer was injected into the deposition chamber for 5 to 30 seconds, argon gas was supplied at 1000 sccm for 30 seconds to perform argon purging. At this time, the pressure inside the reaction chamber was controlled to 1.0 Torr.

Next, ammonia as a reactive gas was injected into the reaction chamber at 1000 sccm for 30 seconds, followed by argon purging for 30 seconds. At this time, the substrate on which a metal thin film is to be formed was heated to 500 to 650° C. By repeating this process 200 to 400 times, an SiN thin film (SixNy thin film) (x and y being integers from 0.5 to 4.5 respectively) with a thickness of 10 nm, which is a self-limiting atomic layer, was formed.

To measure the etching rate, an SiN thin film was etched by immersing the SiN thin film in an LAL500 etchant for 60 seconds, and the reduced thickness was measured as an optical thickness to calculate the etching rate.

### Example 4

2-chloro-2-methyl butane as a shielding compound and Si₂Cl₆ as a thin film precursor compound were prepared, respectively.

The prepared shielding compound was placed in a canister and supplied to a vaporizer heated to 120° C. at a flow rate of 0.1 g/min using a liquid mass flow controller (LMFC) at room temperature. The shielding compound vaporized from the vaporizer was injected into a deposition chamber loaded with a substrate for 5 to 30 seconds, and then argon gas was supplied at 1000 sccm for 30 seconds to perform argon purging. At this time, the pressure inside the reaction chamber was controlled to 1.0 Torr.

Next, the prepared Si₂Cl₆ was placed in a separate canister and supplied to a separate vaporizer heated to 150° C. at a flow rate of 0.1 g/min using a liquid mass flow controller (LMFC) at room temperature. After the thin film precursor compound vaporized from the vaporizer was injected into the deposition chamber for 5 to 30 seconds, argon gas was supplied at 1000 sccm for 30 seconds to perform argon purging. At this time, the pressure inside the reaction chamber was controlled to 1.0 Torr.

Next, ammonia as a reactive gas was injected into the reaction chamber at 1000 sccm for 30 seconds, followed by argon purging for 30 seconds. At this time, the substrate on which a metal thin film is to be formed was heated to 500 to 650° C. By repeating this process 200 to 400 times, an SiN thin film (SixNy thin film) (x and y being integers from 0.5 to 4.5 respectively) with a thickness of 10 nm, which is a self-limiting atomic layer, was formed.

To measure the etching rate, an SiN thin film was etched by immersing the SiN thin film in an LAL500 etchant for 60 seconds, and the reduced thickness was measured as an optical thickness to calculate the etching rate.

### Example 5

The same procedure as in Example 3 was performed except that tert-butyl chloride as a shielding compound and SiH₂Cl₂ as a film precursor compound were prepared.

To measure the etching rate, an SiN thin film was etched by immersing the SiN thin film in an LAL500 etchant for 60 seconds, and the reduced thickness was measured as an optical thickness to calculate the etching rate.

### Example 6

The same procedure as in Example 4 was repeated except that 2-chloro-2-methyl butane was used as a shielding compound and SiH₂Cl₂ was used as a film precursor compound.

To measure the etching rate, an SiN thin film was etched by immersing the SiN thin film in an LAL500 etchant for 60 seconds, and the reduced thickness was measured as an optical thickness to calculate the etching rate.

### Comparative Example 1

An SiN thin film was formed on a substrate in the same manner as in Example 1, except that the shielding compound of Example 1 was not used, and the step of purging an unadsorbed shielding compound was omitted.

### Comparative Example 2

An SiN thin film, which is a self-limiting atomic layer, was formed in the same manner as in Example 1, except that pentane (n-pentane) was used as a shielding compound.

### Comparative Example 3

An SiN thin film, which is a self-limiting atomic layer, was formed in the same manner as in Example 1, except that cyclopentane was used as a shielding compound.

### Comparative Example 4

An SiN thin film was formed on a substrate in the same manner as in Example 3, except that the shielding compound of Example 3 was not used, and the step of purging an unadsorbed shielding compound was omitted.

### Comparative Example 5

An SiN thin film was formed on a substrate in the same manner as in Example 4, except that the shielding compound of Example 4 was not used, and the step of purging an unadsorbed shielding compound was omitted.

### Comparative Example 6

An SiN thin film was formed on a substrate in the same manner as in Example 5, except that the shielding compound of Example 5 was not used, and the step of purging an unadsorbed shielding compound was omitted.

### Comparative Example 7

An SiN thin film was formed on a substrate in the same manner as in Example 6, except that the shielding compound of Example 6 was not used, and the step of purging an unadsorbed shielding compound was omitted.

### EXPERIMENTAL EXAMPLES

### 1) Deposition Evaluation and Deposition Rate Reduction

For the thin film growth rates of the SiN thin films deposited in Examples 1 to 6, and Comparative Examples 1 to 7, using an ellipsometer which is a device capable of measuring optical properties such as thickness and refractive index of the thin film by using the polarization characteristics of light for the manufactured thin film, the thickness of the thin film was measured. Then, the thickness of the thin film deposited per cycle was calculated by dividing the measured thickness by the number of cycles. Based on these results, the thin film growth rate reduction rate was calculated. Specifically, the calculation was performed using Equation 1 below.

$$Reduction rate of thin film growth rate per cycle ( \% ) = [ ( Thin film growth rate per cycle when a shielding compound is used - Thin film growth rate per cycle when a shielding compound is not used ) / Thin film growth rate per cycle when a shielding compound is not used ] \times 100 \qquad [ Equation 1 ]$$

As a result, in the case of Examples 1 to 6 in which the shielding compound according to the present invention was used, compared to Comparative Examples 1, 4, 5, 6, and 7 in which the shielding compound according to the present invention was not used, Comparative Example 2 in which pentane was used, and Comparative Example 3 in which cyclopentane was used, it was confirmed that the reduction rate of thin film growth rate per cycle was greatly improved.

First, when Example 1 using tert-butyl iodide as a shielding compound and Comparative Example 1 not containing tert-butyl iodide were compared, the deposition rate was 0.29 Å/cycle. Compared to 0.35 Å/cycle in Comparative Example 1, it was confirmed that the deposition rate was reduced by more than 20%.

In addition, Comparative Examples 2 and 3, which used pentane or cyclopentane instead of the shielding compound according to the present invention, were also confirmed to have the same deposition rate as Comparative Example 1. At this time, a decrease in the deposition rate may be used as an indicator of improvement in step coverage characteristics because the decrease in the deposition rate means that the CVD deposition characteristics are converted to ALD deposition characteristics.

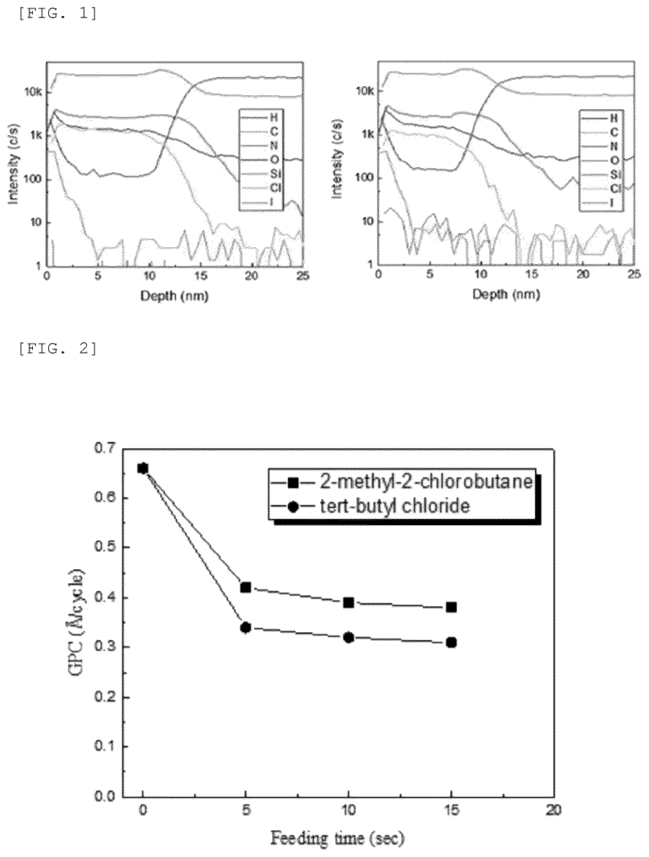

In addition, the feasibility of ppb-level carbon doping was verified through SIMS analysis, and the results obtained are shown in FIG. 1 below.

Specifically, FIG. 1 below includes SIMS analysis graphs of the SiN thin films manufactured in Example 1 and Comparative Example 1.

As shown in FIG. 1, compared to Comparative Example 1 corresponding to the left graph, Cl is significantly reduced in Example 1 corresponding to the right graph.

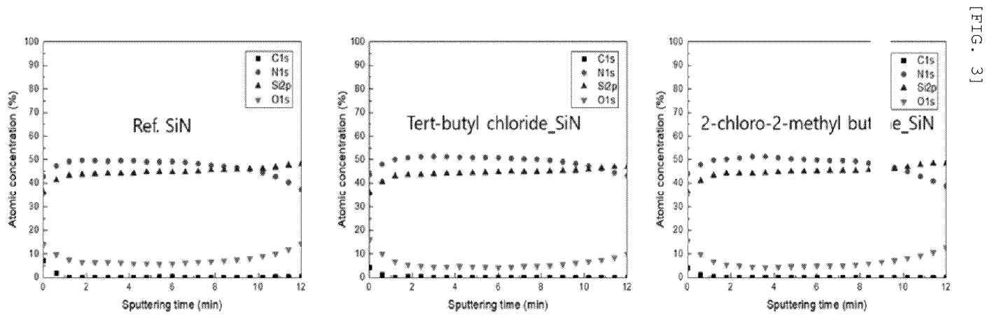

In addition, in FIG. 2 below, the deposition rates obtained in Examples 3 and 4 in which tert-butyl chloride and 2-chloro-2-methyl butane were used as a shielding compound respectively were compared.

FIG. 2 below is a graph that examines the change in deposition rate of the shielding compound of the present invention according to supply time. As shown in FIG. 2, when using the Si₂Cl₆ silicon precursor and the tert-butyl chloride shielding compound, a −35% reduction in deposition rate (0.66 →0.31 Å/cycle) was confirmed when injecting for 15 seconds. When using the 2-chloro-2-methyl butane shielding compound, a −28% reduction in deposition rate (0.66→0.38 Å/cycle) was confirmed when injecting for 15 seconds.

Next, 600° C. deposition rate results according to the injection time of each type of shielding compound using Si₂Cl₆ precursor are shown in Table 1 below.

Table 1 below shows the deposition evaluation results according to deposition temperature when using SiH₂Cl₂ (DCS) silicon precursor.

Tert-butyl chloride was used as a shielding compound, and the shielding compound injection time and purging time for each ALD cycle were 5 seconds and 10 seconds, respectively.

TABLE 1

| | | | | | GPC |
|---|---|---|---|---|---|
| | | | | THK | reduction |
| Temp | | THK | GPC | unit | rate |
| (° C.) | Process | (Å) | (Å/cyc) | (%) | (%) |
| 500 | Ref (DCS) | 144.65 | 0.329 | 2.69 | −64 |
| | Shielding | 130.00 | 0.118 | 2.85 | |
| | agent | | | | |
| | injection | | | | |
| | process | | | | |
| 600 | Ref (DCS) | 275.73 | 0.627 | 1.51 | −65 |
| | Shielding | 241.30 | 0.219 | 0.86 | |
| | agent | | | | |
| | injection | | | | |
| | process | | | | |

As shown in Table 1, deposition rate reduction effects of −64% and −65% were confirmed at deposition temperatures of 500° C. and 600° C., respectively.

### 2) Cl Impurity Reduction Characteristics

To compare the impurity reduction characteristics, i.e., fixed by-product reduction characteristics, of the SiN thin films deposited in Examples 1 to 6 and Comparative Examples 1 to 7, SIMS analysis was performed, and the results are shown in Table 2 below.

Here, the Cl reduction rate (%) was calculated using Equation 2 below.

$$Cl reduction rate = \frac{Comparative Example 1 SIMS Cl intensity - Example SIMS Cl intensity}{Example SIMS Cl intensity} \times 100 \qquad [ Equation 2 ]$$

TABLE 2

| | | | Comparative | Comparative |
|---|---|---|---|---|
| Classification | | Example 1 | Example 1 | Example 2 |
| Cl | 460° C. | 42.8% | 0% | 0% |
| reduction | | (712) | (13855) | (1460) |
| rate | 500° C. | — | 0% | — |
| (Cl | | | (8176) | |
| intensity | 550° C. | — | 0% | — |
| (c/s)) | | | (3104) | |

* Reference thickness of sample thin film: 10 nm. As shown in Table 2, in the case of Example 1 using the shielding compound according to the present invention, compared to Comparative Example 1 that did not use the shielding compound or Comparative Example 2 that used pentane, the Cl intensity was significantly reduced at deposition temperatures of 500° C. and 550° C., respectively, indicating excellent impurity reduction characteristics.

### 3) C Thin Film Impurity Doping Characteristics

XPS quantitative analysis was performed to quantitatively analyze the elements of the SiN thin films deposited in Example 3 and Comparative Example 4.

Specifically, Si₂Cl₆ was used as a silicon precursor, and the shielding compound was injected for 15 seconds and deposition was performed at 600° C.

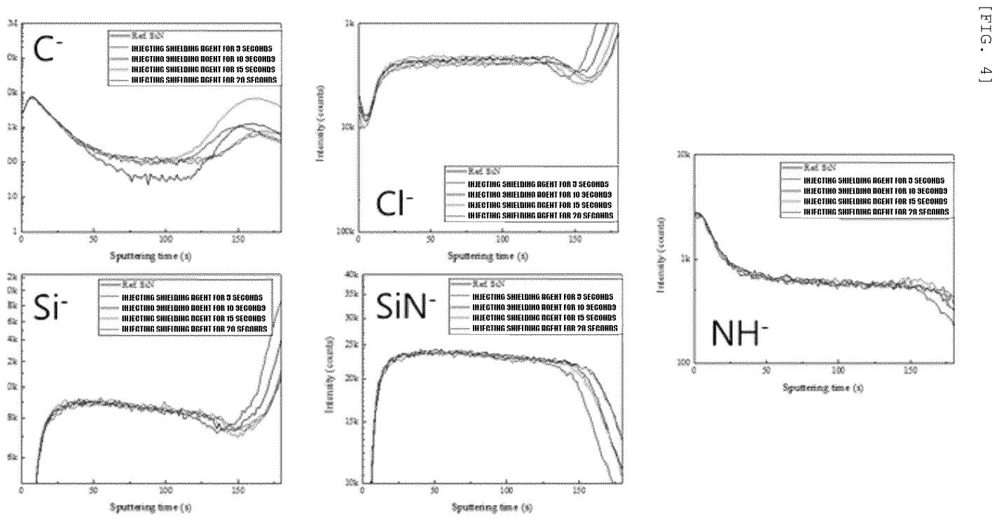

FIG. 3 includes graphs showing the results of depth-dependent elemental analysis through Ar sputtering, for SiN thin films manufactured in Examples 3 and 4 and Comparative Example 4.

As shown in FIG. 3, regardless of the type of shielding compound, no increase in C impurities was observed due to shielding compounds. For reference, trace amounts of oxygen are the result of natural oxidation and contamination by exposure to outside air.

In addition, the possibility of carbon doping at ppb level was verified through SIMS analysis, and the results obtained are shown in FIG. 3 below.

Specifically, Si₂Cl₆ was used as a silicon precursor, and a shielding compound was used. Deposition was performed at a temperature of 600° C. with injection times of no injection, 5 seconds, 10 seconds, 15 seconds, and 20 seconds.

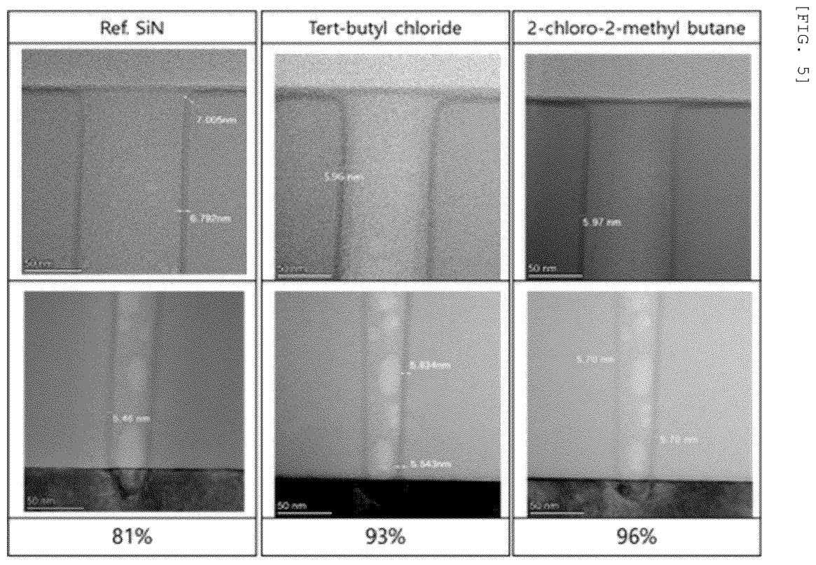

FIG. 4 below includes SIMS analysis graphs of the SiN thin films manufactured in Example 3 and Comparative Example 4. As shown in FIG. 4, although no change in the contents of Si, Cl, and N was observed, it was confirmed that the number of ions corresponding to the secondary ion mass of C released from the specimen increased by approximately 10 times. These C doping results may be additionally confirmed by the etching rate improvement effect because the results also affect the thin film density.

### 4) Step Coverage Characteristics

The step coverage of SiN thin films deposited using a trench substrate with an aspect ratio of 23:1 in Examples 3 and 4 and Comparative Example 4 were confirmed using TEM, and the results are shown in FIG. 5 below.

As shown in FIG. 5, as a result of using the shielding compound according to the present invention, it was confirmed that the step coverage was improved from 81% to 93% and 96%, respectively.

### 5) Etching Rate Characteristics

The etching rate of each specimen was analyzed in Examples 3 and 4 and Comparative Example 4, and the results are shown in Table 3 below.

TABLE 3

| | Etching rate |
|---|---|
| Classification | (nm/min) |
| Comparative Example 4 (Ref. SiN) | 10.2 |
| Example 3 (Tert-butyl chloride_SiN) | 8.7 |
| Example 4 (2-chloro-2-methyl | 7.8 |
| butane_siN) | |

As shown in Table 3, the etching rate of Comparative Example 4 was 10.2 nm/min, and the thin film quality was improved by applying the shielding compound injection process. It was confirmed that the etching rates of Examples 3 and 4 were improved to 8.7 nm/min and 7.8 nm/min, respectively.

1. A shielding compound for a silicon-based thin film, wherein the silicon-based thin film has a film composition represented by SixNy (x and y being integers from 0.5 to 4.5, respectively), and the shielding compound is a saturated compound represented by Chemical Formula 1 below. 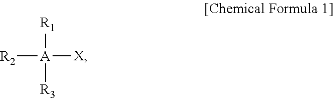
wherein A is carbon;
R₁ and R₃ are independently alkyl groups having 1 to 6 carbon atoms;
R₂ independently has an alkyl group having 1 to 6 carbon atoms or a functional group of a formula of BR₄R₅R₆, wherein B is carbon bonded to A, and R₄, R₅, and R₆ are independently hydrogen, an alkyl group having 1 to 6 carbon atoms, fluorine (F), chlorine (Cl), bromine (Br), or iodine (I); and
X is a halogen element, such as fluorine (F), chlorine (Cl), bromine (Br), or iodine (I).

2. The shielding compound according to claim 1, wherein the shielding compound has a refractive index (a) of 1.38 to 1.52, and has a value (b/a) of 0.003 to 0.033, which is obtained by dividing vapor pressure (25° C., mmHg, b) by the refractive index (a).

3. The shielding compound according to claim 1, wherein the silicon-based thin film is composed of Si₃N₄, Si₂N₃, Si₂N, SiN, or a mixture thereof.

4. The shielding compound according to claim 1, wherein the shielding compound provides a shielding area for a silicon-based thin film.

5. The shielding compound according to claim 4, wherein the shielding area for a silicon-based thin film is formed on an entire region or portion of a substrate on which the silicon-based thin film is formed.

6. The shielding compound according to claim 4, wherein the shielding area for a silicon-based thin film does not remain in the silicon-based thin film, and the silicon-based thin film comprises a halogen compound in an amount of less than 0.01% by weight.

7. The shielding compound according to claim 1, wherein the silicon-based thin film is used as a diffusion barrier, an etch stop film, or a charge trap.

8. A method of forming a silicon-based thin film, comprising injecting a shielding compound having a saturated structure represented by Chemical Formula 1 below into a chamber and shielding a surface of a loaded substrate. 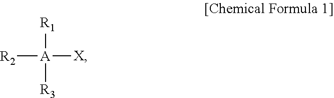
wherein A is carbon;
R₁ and R₃ are independently alkyl groups having 1 to 6 carbon atoms;
R₂ independently has an alkyl group having 1 to 6 carbon atoms or a functional group of a formula of BR₄R₅R₆, wherein B is carbon bonded to A, and R₄, R₅, and R₆ are independently hydrogen, an alkyl group having 1 to 6 carbon atoms, fluorine (F), chlorine (Cl), bromine (Br), or iodine (I); and
X is a halogen element, such as fluorine (F), chlorine (Cl), bromine (Br), or iodine (I).

9. The method according to claim 8, wherein the chamber is an ALD chamber or a CVD chamber.

10. The method according to claim 8, wherein the shielding compound is transported into the chamber by a VFC, DLI, or LDS method, and the silicon-based thin film is a silicon nitride film.

11. A semiconductor substrate fabricated using the method according to claim 8.

12. The semiconductor substrate according to claim 11, wherein the silicon-based thin film has a multilayer structure of two or three layers.

13. A semiconductor device comprising the semiconductor substrate according to claim 11.
